(19) United States
(12) Patent Application Publication
(10) Pub. No.: US 2026/0368401 A1
(43) Pub. Date: Nov. 19, 2026

(54) ADVANCED EMULSION PREDICTION IN RESERVOIRS USING ARTIFICIAL INTELLIGENCE

(71) Applicant: Schlumberger Technology Corporation, Sugar Land, TX (US)

(72) Inventors: Ali Hasan Alhashim, Dhahran (SA); Zouhir Zaouali, Dhahran (SA)

(21) Appl. No.: 19/206,346

(22) Filed: May 13, 2025

(51) Int. Cl. G06F 30/27

(52) U.S. Cl. CPC G06F 30/27

(57) ABSTRACT

A method implements advanced emulsion prediction in reservoirs using artificial intelligence. The method involves ingesting well data. The method further involves preprocessing the well data to generate training data and testing data. The method further involves training a set of emulsion models with the training data to generate an emulsion likelihood from the well data. The method further involves selecting an emulsion model from the set of emulsion models using the testing data. The method further involves generating the emulsion likelihood from the well data. The method further involves visualizing the emulsion likelihood through an interactive user interface to explore one or more data scenarios.

### BACKGROUND

Emulsion formation in reservoirs that produce subsurface fluids poses specific challenges for both upstream and downstream operations. Emulsions, which include mixtures of water and oil, affect mass transfer between phases and the rheological properties of the produced fluid. The size of water and oil droplets within an emulsion influences the properties of the emulsion. Production logging tools face limitations in effectively quantifying the zonal contributions of water and oil flow in the presence of emulsions, often leading to incomplete or imprecise data analysis.

Current methods for addressing emulsion-related challenges may use empirical models or direct measurements from production logging tools. The empirical models or direct measurements may fail to capture the dynamic and complex nature of emulsion formation downhole, resulting in inefficiencies in well management and production optimization. A challenge is to provide an accurate and efficient method to predict and detect downhole emulsions, enabling better decision-making and improved operational outcomes in well management.

### SUMMARY

In general, in one or more aspects, the disclosure relates to a method for advanced emulsion prediction in reservoirs using artificial intelligence. The method involves ingesting well data. The method further involves preprocessing the well data to generate training data and testing data. The method further involves training a set of emulsion models with the training data to generate an emulsion likelihood from the well data. The method further involves selecting an emulsion model from the set of emulsion models using the testing data. The method further involves generating the emulsion likelihood from the well data. The method further involves visualizing the emulsion likelihood through an interactive user interface to explore one or more data scenarios.

In general, in one or more aspects, the disclosure relates to a system that includes at least one processor and an application that executes on the at least one processor. Executing the application performs ingesting well data. Executing the application further performs preprocessing the well data to generate training data and testing data. Executing the application further performs training a set of emulsion models with the training data to generate an emulsion likelihood from the well data. Executing the application further performs selecting an emulsion model from the set of emulsion models using the testing data. Executing the application further performs generating the emulsion likelihood from the well data. Executing the application further performs visualizing the emulsion likelihood through an interactive user interface to explore one or more data scenarios.

In general, in one or more aspects, the disclosure relates to a non-transitory computer readable medium including instructions executable by at least one processor. Executing the instructions performs ingesting well data. Executing the instructions further performs preprocessing the well data to generate training data and testing data. Executing the instructions further performs training a set of emulsion models with the training data to generate an emulsion likelihood from the well data. Executing the instructions further performs selecting an emulsion model from the set of emulsion models using the testing data. Executing the instructions further performs generating the emulsion likelihood from the well data. Executing the instructions further performs visualizing the emulsion likelihood through an interactive user interface to explore one or more data scenarios.

Other aspects of one or more embodiments may be apparent from the following description and the appended claims.

### BRIEF DESCRIPTION OF DRAWINGS

FIG. 1 shows a diagram in accordance with the disclosure.

FIG. 2 shows a method in accordance with the disclosure.

FIG. 3, FIG. 4, and FIG. 5 show examples in accordance with the disclosure.

FIG. 6.1 and FIG. 6.2 show computing systems in accordance with the disclosure.

Similar elements in the various figures may be denoted by similar names and reference numerals. The details of features and elements described in one figure may extend to similarly named features and elements in different figures.

### DETAILED DESCRIPTION

Systems and methods implementing the disclosure address the challenge of predicting emulsions by performing advanced emulsion prediction in oil wells using artificial intelligence. A machine learning methodology from the disclosure may predict and detect downhole emulsions with enhanced precision. The machine learning-based methodology from the disclosure involves the development of a predictive model (referred to as an emulsion model) that simulates conditions within the wellbore, produced fluid, and reservoir environment, incorporating parameters that influence emulsion formation. By providing a robust tool for characterizing water-in-oil emulsions prior to the use of multiphase production logging, the systems and methods of the disclosure operate to deploy fit-for-purpose multiphase production logging tools to improve the accuracy of zonal oil and water contributions from the reservoir.

The machine learning-based methodology encompasses multiple stages: data ingestion, where well data is validated, cleaned, and preprocessed; machine learning model construction, involving the preparation, training, and validation of predictive models; and visualization, design, and deployment, which delivers interactive displays of emulsion likelihoods for user analysis. Systems and methods implementing the disclosure are enhanced with the ability to predict and manage emulsions effectively and is applicable to both existing and newly developed wells, underscoring versatility and broad utility in the field of oil production.

Systems and methods implementing the disclosure may overcome the shortcomings of other methods and leverage state-of-the-art machine learning techniques and represents a specific advancement in downhole emulsion prediction and detection systems and methods implementing the disclosure operate to provide substantial benefits for optimizing well performance and operational efficiency.

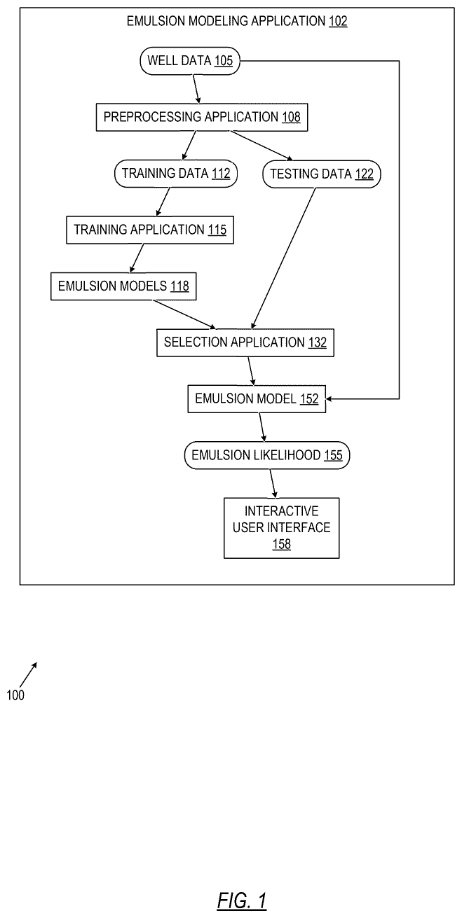

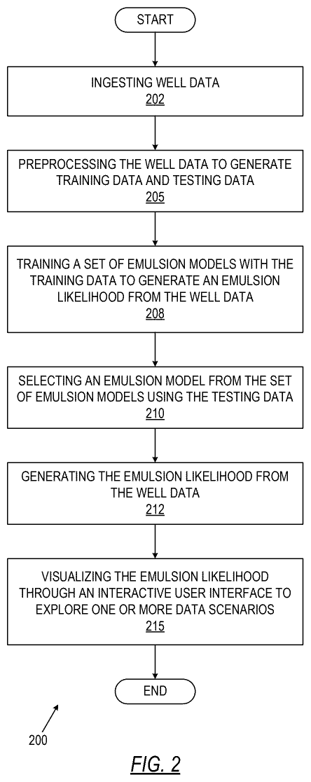

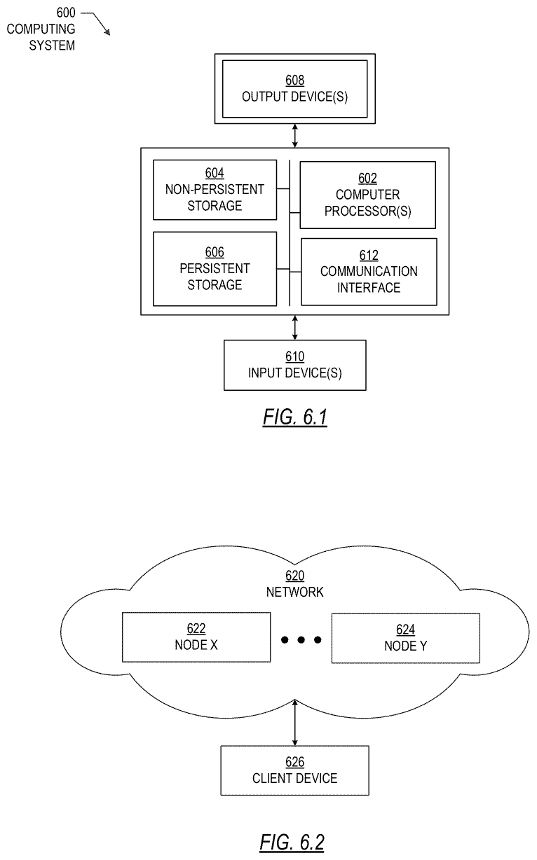

Turning to FIG. 1, the system (100) may utilize computing systems as tools to predict downhole emulsions in oil wells using machine learning techniques. The system (100) includes several interconnected components that work together to transform raw well data into actionable insights for managing emulsion formation in oil and gas production. The components of the system (100) may be implemented as part of a monolithic or distributed computing system such as the computing systems described in FIG. 6.1 and FIG. 6.2.

The emulsion modeling application (102) coordinates data flow and process execution within the system (100). The emulsion modeling application (102) integrates and manages the other components to form a unified workflow for emulsion prediction.

The well data (105) is the input for the system (100) from which predictions are made. The well data (105) includes parameters collected from oil wells, such as fluid properties (e.g., viscosity, oil gravity), wellbore conditions (e.g., temperature, pressure), well completion (e.g., Openhole, perforated liner, smart completion), and reservoir characteristics (e.g., porosity, permeability, production rates), for accurate emulsion prediction, which are further described below.

The well data (105) may include historical data, current data, and potential data. Historical data refers to previously recorded information about the well, such as past production rates, pressure readings, and temperature measurements. Historical data provides a baseline for understanding the well's performance over time and identifying trends or anomalies. Current data encompasses real-time or recently collected information, including up-to-date measurements of fluid properties, wellbore conditions, and reservoir characteristics. Current data may be used for making immediate operational decisions and ensuring the well is functioning optimally. Potential data involves predictive or forecasted information derived from models and simulations, such as expected future production rates, anticipated changes in reservoir conditions, and projected impacts of various operational strategies. Potential data may be used in planning and optimizing future well operations for long-term efficiency and productivity.

The well data (105) may include production rates, well locations, and well deviations. The production rate, measured in barrels per day (bbl/d), assesses the performance of a well and overall productivity. The well location, specified by geographical coordinates, provides the precise geographical position of the well, aiding in mapping and managing oil and gas fields. The well deviation, measured in degrees, indicates the angle at which the well deviates from the vertical, to identify the trajectory of the well for planning drilling operations.

The well data (105) may include information identifying and describing the reservoir, formation, completion type, and completion size. The reservoir may include a name and detail and identify the geological formation that contains the hydrocarbons. The formation may include text describing the formation and may refer to the specific geological layers encountered during drilling, described in text, which may determine extraction methods and predict production rates. The completion type may be a text description of the method used to complete the well, which includes methods such as open hole or cased hole, explaining the design of the well that may impact production. The completion size, measured in inches, may refer to the diameter of the completion equipment of the well, which may affect the flow rate and efficiency of the well.

The well data (105) may include information about a production logging date, surface rates, and water cut. The production logging date tracks the well's performance over time, recording the specific date when production data was logged. Surface rates of oil and water, measured in barrels per day, indicate the well's productivity and manage reservoir health and efficiency. The gross surface rate provides a comprehensive view of the well's output by measuring the total amount of fluids produced at the surface. Water cut, measured in percentage, indicates the proportion of water in the total production, affecting overall production efficiency.

The well data (105) may include information about choke size, downhole pressure and temperature, wellhead pressure, and mixture velocity. Choke size, measured in x/65 inches, refers to the size of the choke used to control the flow rate of the well, optimizing production and preventing damage. Downhole pressure and temperature, measured in psi and degrees Fahrenheit respectively, help in understanding reservoir conditions and managing production. Wellhead pressure, also measured in psi, monitors the well's performance and ensures safe operation. Mixture velocity at emulsion start, measured in feet per minute, affects the efficiency of fluid separation processes.

The well data (105) may include information about oil viscosity, oil American Petroleum Institute (API) gravity, gas oil ratio, water salinity, bubble point pressure and temperature, and the presence of asphaltene, resins, and waxes. Oil viscosity, measured in centipoise, impacts the ease of oil extraction and transportation. Oil API gravity indicates the density of the oil, with higher values representing lighter, more valuable oil. The gas oil ratio, measured in standard cubic feet per stock tank barrel, helps in understanding the composition of the production fluid. Water salinity, measured in kiloparts per million, affects equipment and processing facilities. Bubble point pressure and temperature (e.g., measured in pounds per square inch (PSI) and degrees Fahrenheit respectively) help in reservoir management and predicting production behavior. The presence of asphaltene, resins, and waxes, indicated by text (Yes/No), affects the flow properties of the oil and for which special handling during production and processing may be used.

The preprocessing application (108) functions as a data preparation tool within the system (100). The preprocessing application (108) organizes the well data (105) into a format suitable for machine learning, generating the training data (112) and the testing data (122) as outputs.

The training data (112) includes a subset of the processed well data (105). The training data (112) is used for developing machine learning models (e.g., the emulsion models (118)) within the system (100).

The training application (115) handles the construction of emulsion models in the system (100). The training application (115) employs the training data (112) to develop the emulsion models (118).

The emulsion models (118) comprise a collection of machine learning models within the system (100). The emulsion models (118) operate to predict the likelihood of emulsion formation based on the well data (105). The emulsion models (118) may be of different types using different algorithms, including random forests, logistic regression, gradient boosting, decision trees, etc. Each of the individual different emulsion models within the emulsion models (118) may use similar data extracted from the well data (105). In some implementations, each emulsion model corresponds to an individual type of machine learning model that is trained using the same training data from the wellbore.

The testing data (122) forms another subset of the processed well data (105). The testing data (122) is used to evaluate the performance of the emulsion models (118) created by the system (100).

The selection application (132) operates as a model evaluation tool in the system (100). The selection application (132) assesses the emulsion models (118) to identify the emulsion model with the highest accuracy based on the testing data (122), to be designated as the emulsion model (152).

The emulsion model (152) represents the selected machine learning model from the emulsion models (118) having an accuracy that may be greater than the other emulsion models (118) that were not selected. The emulsion model (152) is selected based on accuracy and reliability in predicting emulsion formation.

The emulsion likelihood (155) is the predictive output produced by the emulsion model (152), which is based on the well data (105). The emulsion likelihood (155) offers a quantitative measure of the probability or extent of emulsion formation based on the well data (105).

The interactive user interface (158) serves as a visualization platform as a part of the system (100). The interactive user interface (158) includes interactive tools, such as graphs, charts, and heat maps to display the emulsion likelihood (155), for users to interact with the predictions.

FIG. 2 shows a flowchart of a method implementing advanced emulsion prediction in reservoirs using artificial intelligence. The method of FIG. 2 may be implemented using the systems described in the other figures, and one or more of the steps may be performed on, or received at, one or more computer processors. The system may include at least one processor and an application that, when executing on the at least one processor, performs the method. A non-transitory computer readable medium may include instructions that, when executed by one or more processors, perform the method. The outputs from various components (including models, functions, procedures, programs, processors, etc.) for performing the method may be generated by applying a transformation to inputs using the components to create the outputs without using mental processes or human activities.

Turning to FIG. 2, the process (200) may predict emulsion likelihoods from well data. The process (200) may include multiple steps (e.g., Block 202 through Block 212) that may execute on the components described in the other figures, including those of FIG. 1, FIG. 6.1, and FIG. 6.2.

Block 202 involves ingesting well data. Ingesting well data may involve data collection, data integration, and data storage.

The data collection process gathers data from a variety of sources at the well site. The data may be gathered from sensors deployed at a well to measure parameters, such as pressure, temperature, flow rate, and chemical composition. Logs from drilling operations, which record metrics like depth, well deviation, resistivity, caliper, neutron density and porosity. Reports that document manual measurements and observations from field personnel may also be gathered. Completion data, such as the casings, tubing and the detailed description of the upper and lower completion are also gathered. The multi-faceted approach to collecting data gathers and complies relevant data reflecting the conditions and operations of a well.

The data integration process consolidates data from multiple sources into a unified dataset. The consolidation involves mapping data to identify relationships between different data sources and merging datasets based on common attributes such as time stamps or location identifiers. Conflicts between datasets, such as differing units of measurement or overlapping data points, are resolved to increase consistency. A unified schema may be utilized to provide a consistent structure for the integrated data so that the relevant information is included and accessible. The integration process makes the data available in a cohesive format for further analysis.

Data storage involves the systematic saving of processed data in a database or data warehouse. The storage system used to store the data may be selected based on the volume and type of data, with options including relational databases, not only scripted query language (NoSQL) databases, and cloud storage solutions. The data is organized to optimize retrieval and analysis, utilizing structures, such as tables, indexes, and partitions. Security measures, including encryption and access controls, are implemented to protect the data from unauthorized access and corruption. Additionally, regular data backups and recovery may be performed to prevent data loss. The process of data storage makes the well data readily available for subsequent analysis and decision-making.

Block 205 involves preprocessing the well data to generate training data and testing data. The preprocessing may involve feature extraction, data segmentation, the handling of missing values, data augmentation, and splitting the data.

Feature extraction involves the identification and extraction of relevant features from the raw well data that are used for predicting emulsions. A determination is made to identify which variables, such as pressure, temperature, flow rate, and chemical composition, are indicative of emulsion formation. By identifying the variables, the dataset is refined to include pertinent information to enhance the efficiency and accuracy of the emulsion models. For example, average pressure and temperature readings over specific intervals may be extracted and used as input features, providing the emulsion models with the relevant data (e.g., the average pressure and temperature) to make accurate predictions.

Data segmentation is the process of dividing the well data into meaningful segments based on criteria, such as time intervals, depth ranges, operational phases, etc. The segmentation may identify specific conditions that may affect emulsion formation to perform a granular analysis of the data. For example, segmenting the data into intervals of 10 meters depth may identify emulsion likelihood variance in relation with depth. Data segmentation may be used to tailor the emulsion models to the unique characteristics of the well data and improve predictive accuracy.

Handling missing values may address gaps or incomplete data points in the well data. Techniques such as imputation, which involves filling in missing values based on statistical methods, or removing records with missing values, are used to maintain the integrity of the dataset. For example, if temperature readings are missing for certain intervals, the values may be inputted using the average temperature of neighboring intervals. The handling of missing values may prevent biases or inaccuracies from the missing data.

Data augmentation involves generating additional data points to enhance the dataset to improve the emulsion models. Techniques including interpolation, extrapolation, or synthetic data generation may be used to create new data points that reflect the underlying patterns and trends in the well data. For example, synthetic data points can be generated by interpolating between existing pressure readings, increasing the dataset size and providing the emulsion models with more diverse training examples.

Splitting the data into training and testing datasets is another step in the preprocessing process. The training data is used to train the emulsion models, while the testing data is used to evaluate the performance. The dataset may be divided using a ratio such as 80:20 or 70:30 so that a larger portion of the data is used for training while still retaining enough data to test the accuracy of the emulsion models.

Preprocessing the well data may involve validating data types of the well data. Validating data types of the well data may include data type identification, consistency checks, type conversion, range validation, format validation, error detection, etc.

Data type identification may automatically identify the data types of each column in the dataset by analyzing the values contained within. The dataset may be scanned to determine whether the values are integers, floats, strings, dates, or other types. Predefined rules and algorithms may be used to classify the data types accurately. For example, a column may be recognized with values like “2025 Mar. 24” as dates, while a column with values like “123.45” may be identified as floats.

Consistency checks check that data types of columns in different records are consistent. Each value in a column may be verified to adhere to the identified data type for the column. For example, if a column is identified as containing integer values, the system checks that the entries are indeed integers and flags any discrepancies, such as the presence of non-integer values.

Type conversion converts data types to expected formats. Values are transformed to match the data type for analysis. For example, if a column contains date values in string format, the system converts the strings to a standardized date format (e.g., YYYY-MM-DD). Similarly, if numerical values are stored as strings, the system converts the numerical values in the strings to integers or floats as appropriate.

Range validation checks that numerical values fall within expected ranges. Acceptable ranges are defined for each numerical column based on domain knowledge or predefined criteria. For example, depth values in a well dataset should be positive and within a realistic range for the specific well. The system scans the dataset to identify any values that fall outside the ranges and flags the values for review.

Format validation validates the format of the data. Values are verified to adhere to expected formats, such as dates being in YYYY-MM-DD format, phone numbers following a specific pattern, etc. The system may use regular expressions and other validation techniques to check the format of each value in the dataset.

Error detection detects and flags anomalies or errors in data types. The dataset is scanned for values that do not conform to the identified data types or expected formats. For example, the system may identify non-numeric values in a numeric column or invalid date formats in a date column.

Preprocessing the well data may involve cleaning the well data to remove noise. The noise may be introduced by duplicates and missing values. Other types of noise may be addressed through smoothing the data.

Removing duplicates identifies and discards duplicate records within the well data. The dataset is scanned for repeated entries that may have been inadvertently recorded multiple times due to errors in data collection or transmission. Records may be compared based on attributes, such as timestamps, sensor IDs, and measurement values, to detect duplicates. Once identified, the redundant entries are removed, thereby reducing the risk of skewed analysis and ensuring that subsequent data processing steps are performed on a clean and accurate dataset.

Handling missing values may address missing values in the well data through a series of imputation techniques designed to fill gaps and ensure data completeness. Initially, an assessment is performed to determine the extent and pattern of missing data, identifying whether the missing values are random or systematic. Based on the assessment, an imputation method, such as interpolation, operates to estimate the missing values based on adjacent data points, or mean/mode imputation, where missing values are replaced with the average or most frequent value of the relevant variable. In cases where records contain missing data that cannot be reliably imputed, the system may remove the records.

Smoothing data applies smoothing techniques to the well data to reduce random noise and enhance the clarity of the underlying signal. Algorithms, such as moving averages, Gaussian smoothing, or other statistical methods that systematically average data points over a specified window or apply a weighted average to adjacent points may be used. By doing so, the impact of transient fluctuations and erratic variations that may arise from sensor inaccuracies, environmental factors, or other sources of noise may be mitigated. The smoothing process is calibrated to preserve trends and patterns in the data while removing spurious anomalies that may distort the analysis.

Preprocessing the well data may involve encoding categorical variables. Different types of encoding may be used, such as label encoding, one hot encoding, binary encoding frequency encoding, target encoding, ordinal encoding, etc.

Label encoding involves assigning a unique integer to each category within a categorical variable. Categorical data is transformed into numerical data, facilitating the use in machine learning algorithms. For instance, if the categorical variable is “well type” with categories such as “exploratory,” “development,” and “production,” label encoding would assign integers 0, 1, and 2 to the categories respectively. Label encoding may introduce an ordinal relationship between categories, which may not be appropriate for the types of categorical data.

One-hot encoding is a technique that converts categorical variables into binary vectors. Each category is represented by a separate binary column, where the presence of a category is indicated by a value of 1 and the absence by a value of 0. For example, if the categorical variable is “well type” with categories “exploratory,” “development,” and “production,” one-hot encoding would create three new columns identified as “well_type_exploratory,” “well_type_development,” and “well_type_production.” Each row in the dataset would have binary values in the columns, indicating the presence or absence of each well type. One-hot encoding avoids introducing ordinal relationships between categories and is useful for algorithms that use numerical input without inherent order.

Binary encoding is a method that converts categorical variables into binary digits. Each category is assigned a unique binary code, which is then used to represent the category in the dataset. For instance, if the categorical variable is “well type” with categories “exploratory,” “development,” and “production,” binary encoding would assign binary codes such as 00, 01, and 10 to the categories respectively. Binary encoding reduces the dimensionality of the data compared to one-hot encoding and is suitable for large datasets with numerous categories. Binary encoding ensures that the data remains numerical while avoiding the introduction of ordinal relationships between categories.

Frequency encoding involves encoding categories based on the frequency of occurrence within the dataset. Each category is assigned a numerical value corresponding to frequency, allowing algorithms to leverage the distribution of categories in the data. For example, if the categorical variable is “well type” and the categories “exploratory,” “development,” and “production” appear 50, 30, and 20 times respectively, frequency encoding would assign values 50, 30, and 20 to the categories. Frequency encoding captures the prevalence of each category, providing valuable information to algorithms that can benefit from understanding category distributions.

Target encoding is a technique that encodes categories based on the mean of the target variable for each category. Target encoding involves calculating the average value of the target variable for each category and using the average as the encoded value. For instance, if the target variable is “production rate,” and the average production rates for categories “exploratory,” “development,” and “production” are 100, 150, and 200 barrels per day respectively, target encoding would assign values 100, 150, and 200 to the categories. Target encoding leverages the relationship between categorical variables and the target variable, providing algorithms with meaningful numerical representations that reflect the target variable's influence.

Ordinal encoding assigns a rank or order to categories based on a predefined criterion. Ordinal encoding is suitable for categorical variables with inherent order or hierarchy. For example, if the categorical variable is “well type” with categories “exploratory,” “development,” and “production,” ordinal encoding would assign values 1, 2, and 3 to the categories respectively. The encoded values reflect the natural order of the categories, allowing algorithms to process the data in a manner that respects the hierarchical relationships. Ordinal encoding is useful for variables where the order of categories carries specific meaning.

Encoding categorical variables is a transformation to convert non-numerical data into a format that machine learning models can process effectively. Well data often includes categorical variables, such as well types (e.g., vertical, horizontal) or fluid classifications (e.g., light oil, heavy oil), which cannot be directly used in mathematical computations. Encoding techniques like one-hot encoding or label encoding are applied. One-hot encoding creates binary columns for each category, while label encoding assigns a unique numerical value to each category. The transformation allows the machine learning algorithms to interpret and utilize categorical information, ensuring that the relevant features are incorporated into the emulsion models.

Preprocessing the well data may involve normalizing the well data across different datasets. Different types of normalization may be performed, including standardization, min-max scaling, log transformation, z-score normalization, etc.

The process of standardization involves transforming the well data to have a mean of zero and a standard deviation of one. The transformation is achieved by subtracting the mean (μ) of the dataset from each data point (x) and then dividing the result by the standard deviation (σ). The formula used for the transformation is

$$z = \frac{( x - μ )}{σ} .$$

Standardization centers the data around zero and scaled according to variability, which helps in mitigating the effects of differing scales and units across various datasets.

Min-max scaling is a normalization technique that scales the well data to fit within a specific range, which may be between 0 and 1. Min-max scaling is accomplished by subtracting the minimum value (xₘᵢₙ) of the dataset from each data point (x) and then dividing the result by the range of the dataset, which is the difference between the maximum (xₘₐₓ) and minimum values. The formula for the transformation is

$${x}^{′} = \frac{( x - {x}_{min} )}{( {x}_{max} - {x}_{min} )} .$$

Min−max scaling sales the data points to be proportionally adjusted to a common scale, which may be used by algorithms that use distance metrics, such as k-nearest neighbors and support vector machines. Normalizing the data to a uniform range improves the comparability and interpretability of the data across different datasets.

Log transformation is a normalization technique used to reduce skewness and bring the well data closer to a normal distribution. Log transformation is useful for data that exhibits exponential growth or has a long tail distribution. The log transformation is performed by applying the natural logarithm to each data point (x), which may include an added constant to handle zero values, resulting in the formula x′=log(x+1). By compressing the range of the data, log transformation reduces the impact of extreme values and stabilizes the variance, making the data more suitable for statistical analysis and machine learning models.

Block 208 involves training a set of emulsion models with the training data to generate an emulsion likelihood from the well data. The training may include model initialization as well as model training.

A variety of machine learning models are initialized to create a set of emulsion models. The initialization sets the foundation for the subsequent training process. The algorithms may include, but are not limited to, decision trees, random forests, neural networks, support vector machines, ensemble methods, etc. The emulsion model for each algorithm is initialized with a set of default or specified hyperparameters that define an initial configuration. For instance, a decision tree may be initialized with parameters, such as maximum depth, minimum samples per leaf, and splitting criteria. Similarly, a neural network may be initialized with parameters including the number of layers, number of neurons per layer, activation functions, and learning rate. The initialization process also involves setting up the computational environment, which may include allocating memory, defining data structures, and configuring software libraries used for model training.

The initialized emulsion models are trained using the preprocessed training data. The training process involves feeding the data into each emulsion model and iteratively adjusting the model parameters to minimize prediction error. For each algorithm, the training data is divided into batches, and the emulsion model processes the batches in a series of iterations known as epochs. During each epoch, the emulsion model updates model parameters based on the error calculated from the predictions. For example, in a neural network, the backpropagation algorithm is used to adjust the weights and biases of the neurons to reduce the loss function. In decision trees, the emulsion model splits the data at various nodes based on the chosen criteria to optimize the prediction accuracy. The training process also includes regularization techniques to prevent overfitting so that the emulsion models generalize well to unseen data. Performance metrics, such as loss, accuracy, precision, recall, F1 score, etc., may be continuously monitored to track the progress of the training. Early stopping criteria may be implemented to halt the training if performance on the validation set starts to degrade in order to prevent overfitting.

Training the set of emulsion models may involve executing the set of emulsion models using the training data to generate updates to the set of emulsion models.

Executing the set of emulsion models using the training data involves a process where each emulsion model is applied to the training data to evaluate model performance and generate iterative updates. Initially, the training data, which has been preprocessed to ensure consistency and uniformity, is fed into each emulsion model. The emulsion models then undergo a series of computational operations, including feature extraction, pattern recognition, and statistical analysis, to generate outputs that predict the likelihood of emulsion formation based on the input data. During the execution phase, the emulsion models continuously adjust the parameters and weights to better fit the training data, using techniques such as gradient descent, backpropagation, etc. The adjustments operate to reduce prediction errors and increase the accuracy of the emulsion models.

Training the set of emulsion models may involve updating the set of emulsion models with the updates to improve a set of predictive accuracies of the set of emulsion models. Updating the set of emulsion models with the updates to improve a set of predictive accuracies of the set of emulsion models involves a process that enhances the performance and reliability of the emulsion models. Initially, the emulsion models are executed using the training data, to generate preliminary outputs and predictions. The outputs are analyzed to determine the accuracy and efficacy of each emulsion model. Based on the analysis, specific updates are formulated, which may include adjustments to model parameters, incorporation of additional features, or refinement of the algorithms used. The updates are then applied to the emulsion models, followed by a re-execution of the emulsion models to assess the impact of the changes. The iterative cycle of execution, analysis, and updating may continue until one or more of the emulsion models achieve a predefined level of predictive accuracy.

Block 210 involves selecting an emulsion model from the set of emulsion models using the testing data. To select an emulsion model, a computing system may apply testing data to each emulsion model to generate predicted emulsion likelihoods. The predictions are compared with actual observations to evaluate performance. The accuracy of each emulsion model is calculated and ranked based on accuracy and error rates. The emulsion model with the highest accuracy and lowest error rate may then be selected for deployment.

Selecting the emulsion model may involve applying the testing data to the set of emulsion models to generate a set of predicted emulsion likelihoods. A computing system may apply the testing data to each emulsion model within the set of emulsion models. The test data is input, after being preprocessed and validated, into each emulsion model to generate a set of predicted emulsion likelihoods. The testing data serves as a benchmark to evaluate the performance of the emulsion models under conditions that simulate real-world scenarios.

Selecting the emulsion model may involve comparing the set of predicted emulsion likelihoods with a set of observations to measure model performance and generate a set of model accuracies. Once the predicted emulsion likelihoods are generated by each emulsion model, the predictions are compared with a set of actual observations or ground truth data. The comparisons are used to evaluate the accuracy of the predictions of the emulsion models. The differences between the predicted likelihoods and the actual observations are calculated to identify the emulsion models that are more closely aligned with the real-world data.

The accuracy of each emulsion model is calculated based on the comparison results to generate a set of model accuracies. The accuracy calculation may involve statistical analysis to determine the frequency that the model predictions match the actual observations. Metrics, such as mean squared error, precision, recall, F1 score, etc., may be used to quantify the accuracy. The metrics may be aggregated (e.g., average, weighted average, etc.) to provide an assessment of model performance.

After calculating the accuracies, the emulsion models may be ranked according to the performance metrics. Emulsion models may be ordered from highest to lowest based on the accuracy scores and error rates. The ranking process identifies the emulsion models that are reliable for practical deployment. Other factors may be factored into the ranking, such as computational efficiency and robustness to ensure that the selected emulsion model is accurate, efficient and stable under various conditions.

Selecting the emulsion model may involve selecting the emulsion model from the set of emulsion models using the set of model accuracies. The emulsion model with the highest accuracy and lowest error rate may be selected for deployment. The selection is based on the evaluation and ranking of the emulsion models with each other. The selected emulsion model is identified as the most suitable for predicting downhole emulsions based on the performance from handling the testing data. The selection process may be automatically documented with a report that identifies the calculations and rationale behind the selection of a specific emulsion model to increase reproducibility and accuracy of the model selection process.

Block 212 involves generating the emulsion likelihood from the well data. To generate the emulsion likelihood from the well data, the selected emulsion model may be deployed to a suitable computational environment to access input data (e.g., well data). The emulsion model processes the input data using the weights and parameters generated by the training algorithms, applying the learned patterns and relationships stored in the weights and parameters to the new data. The calculated emulsion likelihood is generated as an output, which may be a numerical value, a probability score, or a classification indicating the risk level of emulsion formation.

Generating the emulsion likelihood may involve executing the emulsion model using current data from the well data to generate the emulsion likelihood. The current well data includes parameters and measurements relevant to the well conditions and is fed into the emulsion model that was selected.

Block 215 involves visualizing the emulsion likelihood through an interactive user interface to explore one or more data scenarios. The process of visualizing the emulsion likelihood involves mapping the data to visual elements, such as graphs, charts, and heat maps. Graphs may be generated to represent the emulsion likelihood over time or across different parameters, while charts categorize and display the data. Heat maps may be constructed to show the intensity and distribution of emulsion likelihood. Interactive controls, such as sliders and dropdowns, may be implemented to adjust parameters and see dynamic updates in the visualizations. Zoom and pan functionalities may be added for detailed exploration. Multiple visual layers may be overlaid for comparative analysis, and options to export visualizations in various formats.

Visualizing the emulsion likelihood may involve displaying the emulsion likelihood in a graph on a user interface. Different types of graphs, such as line graphs, bar graphs, scatter plots, etc., may be displayed to represent emulsion likelihood data. Data points are plotted on the graph with appropriate axes along with customization options, which may include colors, labels, scales, etc. Interactive features, including zooming, panning, tooltips, etc., may be implemented to increase engagement. Real-time updates may be displayed as new data is ingested or parameters are adjusted. Annotations may be added directly on the graph to add additional context. Multiple graphs may be overlaid for comparative analysis.

Visualizing the emulsion likelihood may involve executing the interactive user interface to display the emulsion likelihood using one or more graphs, charts, and heat maps for different data scenarios and adjust parameters to interactively display potential outcomes. Executing the interactive user interface includes several processes from data visualization through user interaction and feedback. Data visualization is achieved through the display of various graphs and charts, such as line graphs, bar charts, and scatter plots, which are used to illustrate trends, distributions, and relationships within the data. Heat maps represent data density and patterns, utilizing color gradients to highlight areas of high and low likelihood, thereby making trends and anomalies more apparent. Interactive features are incorporated, allowing users to adjust parameters like temperature, concentration, or time through sliders, dropdown menus, input fields, etc., with real-time updates reflecting the new data scenarios. The dynamic interaction is used to explore different outcomes. The computing system processes the input well data along with parameter adjustments using algorithms and emulsion models to calculate the emulsion likelihood, and the visualizations are rendered using visualization libraries or frameworks for accuracy and responsiveness. User interaction and feedback is used to explore different data scenarios and observe changes in the visualizations, aiding in understanding the impact of various factors on emulsion likelihood and supporting decision-making through clear and intuitive representations of potential outcomes.

The process (200) may further involve transmitting a real-time notification through the interactive user interface based on the emulsion likelihood. The calculated emulsion likelihood is compared against predefined thresholds to determine if a notification is triggered. If the threshold is satisfied, a notification message is generated, containing relevant information about the emulsion likelihood and actions that may be executed. The interactive user interface is updated to display the generated notification in real-time.

The process (200) may further involve using the selected emulsion model to optimize well production parameters. The selected emulsion model may be used to simulate different production scenarios to predict the emulsion likelihood and overall well performance based on changes in production parameters. Optimization algorithms are used to identify a set of production parameters for flow rate optimization that maximizes well performance while minimizing emulsion formation. Based on the optimization results, real-time adjustments to the production parameters are made using the selected emulsion model, continuously monitoring well conditions and updating parameters to maintain optimal performance.

The process (200) may further involve using the emulsion likelihood to dynamically adjust chemical injection rates to prevent emulsion formation. The emulsion likelihood may be calculated based on real-time data collected from sensors monitoring the chemical composition and flow rates within the system. Based on the predictions of emulsion likelihood, the injection rates of chemicals are adjusted to inhibit emulsion formation. Continuous monitoring and adjustments may be performed to maintain system stability and efficiency, to prevent disruptions caused by emulsions.

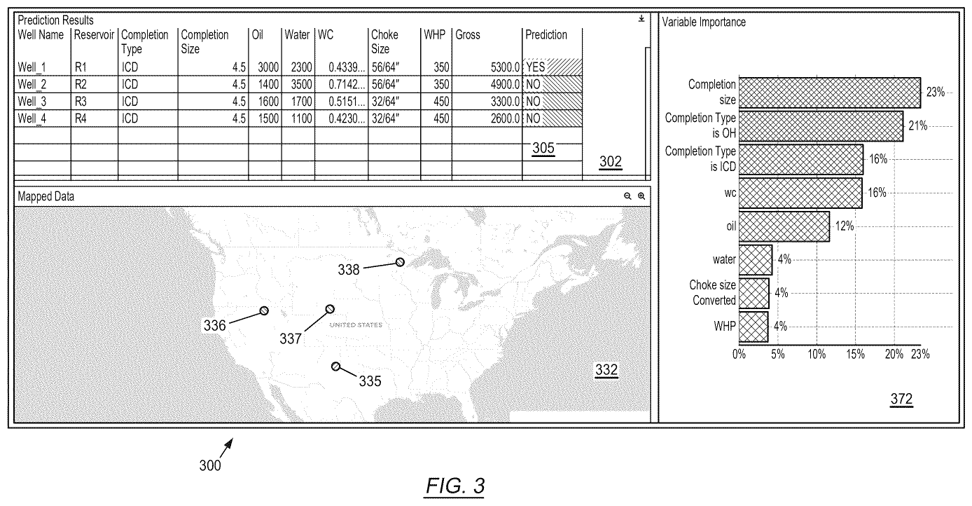

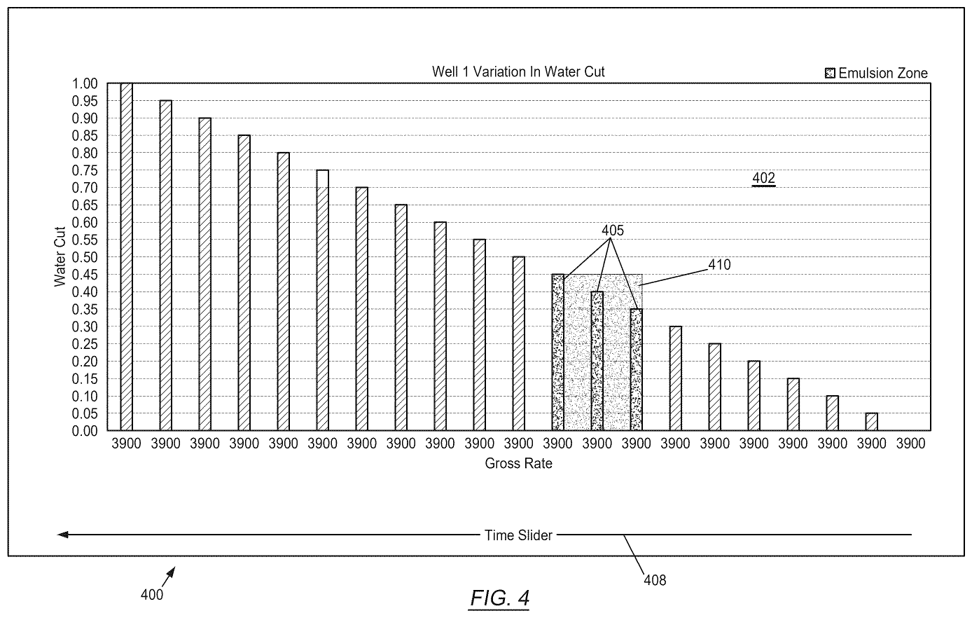

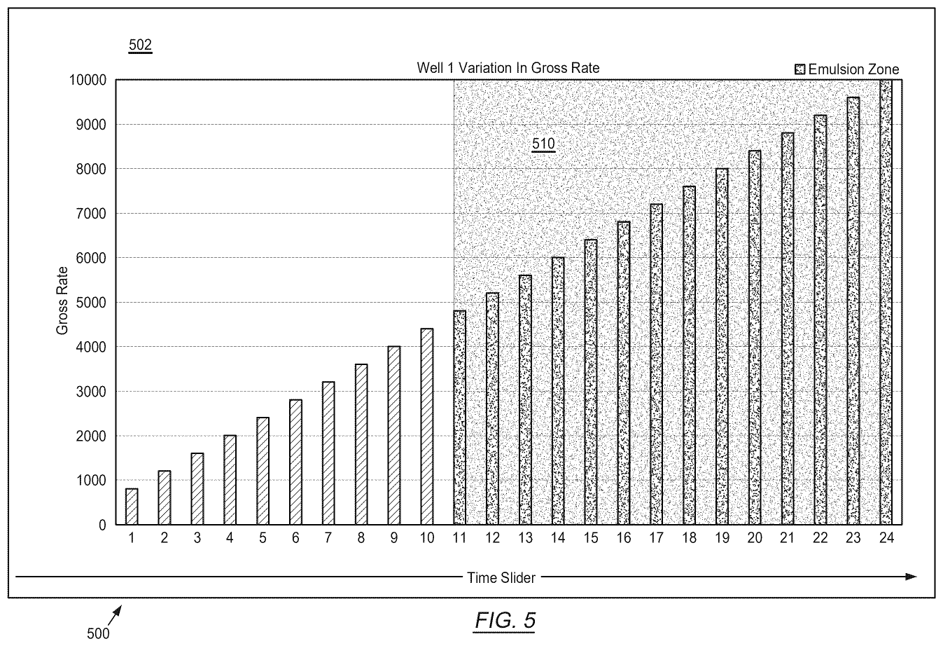

Turning to FIG. 3, the user interface (300) displays emulsion predictions for well data from multiple wells in an interactive user interface. The user interface (300) includes multiple interactive views, including the table view (302), the map view (332), and the chart view (372).

The table view (302) displays the table (305). The table (305) includes rows and columns for the well data and the emulsion predictions. The well may have periodic values, e.g., values that are daily, weekly, monthly, yearly, etc.

The column labeled “Well name” includes text data that identifies the wells, e.g., the string “Well_1”. The column labeled “Reservoir” includes text data that identifies reservoirs, e.g., the string “R1”. The column labeled “completion Type” includes categorical data that identifies the type of completion, e.g., “OH”, “ICD”, etc. The column labeled “Completion size” includes numerical data that identifies the size of a completion, e.g., “4.5”. The column labeled “oil” includes numerical data that identifies the daily amount of oil produced, e.g., “3000” for the well labeled “Well_1”. The column labeled “water” includes numerical data that identifies the daily amount of water from the well, e.g., “2300” for the well labeled “Well_1”. The column labeled “wc” includes numerical data that identifies the water cut (volume of water divided by the volume of water plus oil), e.g., “0.4339” for the well labeled “Well_1”. The column labeled “Choke size” includes numerical data that identifies the choke size of the well, e.g., “ 56/64” for the well labeled “Well_1”. The column labeled “WHP” includes numerical data that identifies the wellhead pressure, e.g., “350” for the well labeled “Well_1”. The column labeled “Gross” includes numerical data that identifies the total amount of fluid produced (oil plus water), e.g., “5300” for the well labeled “Well_1”. The column labeled “prediction” includes categorical data that indicates if a well has an emulsion issue, e.g., “YES” for the well labeled “Well_1”.

The data in the “prediction” column may be generated from processing the well data columns with an emulsion model that is trained and selected with historical data. The emulsion model may output an emulsion likelihood that is a rational value in the range of 0 to 1. A threshold may be used to convert the rational value of the emulsion likelihood to a categorical value. For example, when the emulsion likelihood is greater than or equal to a threshold of 0.6, the categorical value may be “YES” and “NO” otherwise.

The cells displayed in the “prediction” column may include highlighting that corresponds to different categorical values. For example, the value “YES” may be highlighted red to indicate that there may be an emulsion issue for a well. The value “NO” may be highlighted green to indicate that there is not an emulsion issue for a well.

The four rows of the table (305) identify four different wells for which information is provided. The wells corresponding to the rows of the table (305) may be displayed in the map view (332).

The map view (332) displays a geographical map with the locations of the wells from the table (305) using the indicators (335) through (338). The indicator (335) corresponds to the well labeled “Well_1” from the table (305). The indicator (336) corresponds to the well labeled “Well 2” from the table (305). The indicator (337) corresponds to the well labeled “Well 3” from the table (305). The indicator (338) corresponds to the well labeled “Well 4” from the table (305). The colors of the indicators (335) through (338) may be the same as the highlighting for the cells of the “prediction” column to indicate the presence, or lack thereof, of any motion issue at the well.

The chart view (372) displays a bar chart with an analysis of the data for the predictions. The rows of the chart view (372) identify variables (i.e., columns) from the table (305). The values for each of the rows and corresponding bars in the chart view (372) identify the contribution of the variable to the predictions made by the emulsion model. The bars may be shaded with darker colors, identifying variables with higher contribution and lighter colors, identifying variables with lesser contribution.

The user interface (300) may be interactive. For example, a user may change values in the cells of the table (305). Responsive to a change in a value of a cell, the prediction for that row may be updated as well as the highlighting for the cell and the color in the map view (332). The values in the chart view (372) may also be updated based on changes to the values in the table (305).

Turning to FIG. 4, the user interface (400) includes the chart (402) that displays emulsion likelihood information generated with an emulsion model that is selected from training a group of emulsion models for the well identified as “Well_1”, which corresponds to the well labeled “Well_1” in the table (305) of FIG. 3. The chart (402) shows the water cut (the y axis) for a gross rate of (3900) (displayed on the x axis). The emulsion predictions are displayed by changing the color of the bars where the size of the bars represent the water cut. The emulsion predictions are based on time variance due to changes in gross rate, choke size, and water cut percentage. The differences in the sizes of the bars on the chart (402) may be due to the differences in the choke size.

The bars (405) may be shaded a different color (red) as compared to the other bars (shaded blue). The shading of the bars in the chart (402) represents the emulsion prediction based on an emotional likelihood generated by a selected emulsion model.

Interaction with the time slider (408) (e.g., by sliding left or right) may change well data used to make the emulsion predictions displayed on the chart (402). The sizes of the bars as well as the colors indicating the emotional prediction may change in response to interaction with the time slider (408).

The area (410) identifies an emulsion zone on the chart (402) that may correspond to specific variable values of water cut, gross rate, and choke size. The height of the area (410) is the length of the longest bar within the area (410). The width of the area (410) is the maximum distance between the bars within the area (410).

Turning to FIG. 5, the user interface (500) is updated from the user interface (400) of FIG. 4. The updates to the user interface (500) are in response to changes to the variables displayed on the chart (502). Where the chart (402) of FIG. 4 displayed variation in water cut, the chart (502) of FIG. 5 displays variation in gross rate. More bars in the chart are in the area (510) of the emulsion zone showing a sensitivity of the emulsion zone to the gross rate.

One or more embodiments may be implemented on a computing system specifically designed to achieve an improved technological result. When implemented in a computing system, the features and elements of the disclosure may be implemented with application specific integrated circuits and provide a significant technological advancement over computing systems that do not implement the features and elements of the disclosure. Any combination of mobile, desktop, server, router, switch, embedded device, or other types of hardware may be improved by including the features and elements described in the disclosure.

For example, as shown in FIG. 6.1, the computing system (600) may include one or more computer processor(s) (602), non-persistent storage device(s) (604), persistent storage device(s) (606), a communication interface (608) (e.g., Bluetooth interface, infrared interface, network interface, optical interface, etc.), and numerous other elements and functionalities that implement the features and elements of the disclosure. The computer processor(s) (602) may be an integrated circuit for processing instructions and may include multiple application specific integrated circuits to implement the features and elements described above. The computer processor(s) (602) may be one or more cores, or micro-cores, of a processor. The computer processor(s) (602) includes one or more processors. The application specific integrated circuits of the computer processor(s) (602) may include a central processing unit (CPU), a graphics processing unit (GPU), a tensor processing unit (TPU), combinations thereof, etc.

The non-persistent storage device(s) (604) and the persistent storage device(s) (606) form at least part of a memory that stores the data structures that implement the features and elements described above. A data structure may be stored at a location within the memory that may be referenced by multiple data structures.

The input device(s) (610) may include a touchscreen, keyboard, mouse, microphone, touchpad, electronic pen, or any other type of input device. The input device(s) (610) may receive inputs from a user that are responsive to data and messages presented by the output device(s) (612). The inputs may include text input, audio input, video input, etc., which may be processed and transmitted by the computing system (600) in accordance with one or more embodiments. The communication interface (608) may include an integrated circuit for connecting the computing system (600) to a network (not shown) (e.g., a local area network (LAN), a wide area network (WAN), such as the Internet, mobile network, or any other type of network) or to another device, such as another computing device, and combinations thereof.

Further, the output device(s) (612) may include a display device, a printer, external storage, or any other output device. One or more of the output device(s) (612) may be the same or different from the input device(s) (610). The input device(s) (610) and output device(s) (612) may be locally or remotely connected to the computer processor(s) (602). Many different types of computing systems exist, and the aforementioned input device(s) (610) and output device(s) (612) may take other forms. The output device(s) (612) may display data and messages that are transmitted and received by the computing system (600). The data and messages may include text, audio, video, etc., and include the data and messages described above in the other figures of the disclosure.

Software instructions in the form of computer readable program code to perform embodiments may be stored, in whole or in part, temporarily or permanently, on a non-transitory computer readable medium, such as a solid state drive (SSD), compact disk (CD), digital video disk (DVD), storage device, a diskette, a tape, flash memory, physical memory, or any other computer readable storage medium. Specifically, the software instructions may correspond to computer readable program code that, when executed by the computer processor(s) (602), is configured to perform one or more embodiments, which may include transmitting, receiving, presenting, and displaying data and messages described in the other figures of the disclosure.

The computing system (600) in FIG. 6.1 may be connected to, or be a part of, a network. For example, as shown in FIG. 6.2, the network (620) may include multiple nodes (e.g., node X (622) and node Y (624), as well as extant intervening nodes between node X (622) and node Y (624)). Each node may correspond to a computing system, such as the computing system shown in FIG. 6.1, or a group of nodes combined may correspond to the computing system shown in FIG. 6.1. By way of an example, embodiments may be implemented on a node of a distributed system that is connected to other nodes. By way of another example, embodiments may be implemented on a distributed computing system having multiple nodes, where each portion may be located on a different node within the distributed computing system. Further, one or more elements of the aforementioned computing system (600) may be located at a remote location and connected to the other elements over a network.

The nodes (e.g., node X (622) and node Y (624)) in the network (620) may be configured to provide services for a client device (626). The services may include receiving requests and transmitting responses to the client device (626). For example, the nodes may be part of a cloud computing system. The client device (626) may be a computing system, such as the computing system shown in FIG. 6.1. Further, the client device (626) may include or perform all or a portion of one or more embodiments.

The computing system of FIG. 6.1 may include functionality to present data (including raw data, processed data, and combinations thereof), such as results of comparisons and other processing. For example, presenting data may be accomplished through various presenting methods. Specifically, data may be presented by being displayed in a user interface, transmitted to a different computing system, and stored. The user interface may include a graphical user interface (GUI) that displays information on a display device. The GUI may include various GUI widgets that organize what data is shown, as well as how data is presented to a user. Furthermore, the GUI may present data directly to the user, e.g., data presented as actual data values through text, or rendered by the computing device into a visual representation of the data, such as through visualizing a data model, which may be generated using the emulsion models described above.

As used herein, the term “connected to” contemplates multiple meanings. A connection may be direct or indirect (e.g., through another component or network). A connection may be wired or wireless. A connection may be a temporary, permanent, or a semi-permanent communication channel between two entities.

The various descriptions of the figures may be combined and may include, or be included within, the features described in the other figures of the application. The various elements, systems, components, and steps shown in the figures may be omitted, repeated, combined, or altered as shown in the figures. Accordingly, the scope of the present disclosure should not be considered limited to the specific arrangements shown in the figures.

In the application, ordinal numbers (e.g., first, second, third, etc.) may be used as an adjective for an element (i.e., any noun in the application). The use of ordinal numbers is not to imply or create any particular ordering of the elements, nor to limit any element to being only a single element unless expressly disclosed, such as by the use of the terms “before”, “after”, “single”, and other such terminology. Rather, ordinal numbers distinguish between the elements. By way of an example, a first element is distinct from a second element, and the first element may encompass more than one element and succeed (or precede) the second element in an ordering of elements.

Further, unless expressly stated otherwise, the conjunction “or” is an inclusive “or” and, as such, automatically includes the conjunction “and,” unless expressly stated otherwise. Further, items joined by the conjunction “or” may include any combination of the items with any number of each item, unless expressly stated otherwise.

In the above description, numerous specific details are set forth in order to provide a more thorough understanding of the disclosure. However, it will be apparent to one of ordinary skill in the art that the technology may be practiced without these specific details. In other instances, well-known features have not been described in detail to avoid unnecessarily complicating the description. Further, other embodiments not explicitly described above can be devised which do not depart from the scope of the claims as disclosed herein. Accordingly, the scope should be limited only by the attached claims.

What is claimed is:

1. A method comprising:
ingesting well data;
preprocessing the well data to generate training data and testing data;
training a set of emulsion models with the training data to generate an emulsion likelihood from the well data;
selecting an emulsion model from the set of emulsion models using the testing data;
generating the emulsion likelihood from the well data; and
visualizing the emulsion likelihood through an interactive user interface to explore one or more data scenarios.

2. The method of claim 1, wherein preprocessing the well data comprises:
validating data types of the well data;
cleaning the well data to remove noise;
encoding categorical variables; and
normalizing the well data across different datasets.

3. The method of claim 1, wherein training the set of emulsion models comprises:
executing the set of emulsion models using the training data to generate updates to the set of emulsion models; and
updating the set of emulsion models with the updates to improve a set of predictive accuracies of the set of emulsion models.

4. The method of claim 1, wherein selecting the emulsion model comprises:
applying the testing data to the set of emulsion models to generate a set of predicted emulsion likelihoods;
comparing the set of predicted emulsion likelihoods with a set of observations to measure model performance and generate a set of model accuracies; and
selecting the emulsion model from the set of emulsion models using the set of model accuracies.

5. The method of claim 1, wherein generating the emulsion likelihood comprises:
executing the emulsion model using current data from the well data to generate the emulsion likelihood.

6. The method of claim 1, wherein visualizing the emulsion likelihood comprises:
displaying the emulsion likelihood in a graph on a user interface.

7. The method of claim 1, wherein visualizing the emulsion likelihood comprises:
executing the interactive user interface to display the emulsion likelihood using one or more graphs, charts, and heat maps for different data scenarios and adjust parameters to interactively display potential outcomes.

8. The method of claim 1, further comprising:
transmitting a real-time notification through the interactive user interface based on the emulsion likelihood.

9. The method of claim 1, wherein the selected emulsion model is used to optimize well production parameters.

10. The method of claim 1, wherein the emulsion likelihood is used to dynamically adjust chemical injection rates to prevent emulsion formation.

11. A system comprising:
at least one processor; and
an application that, when executing on the at least one processor, performs stored operations comprising:
ingesting well data,
preprocessing the well data to generate training data and testing data,
training a set of emulsion models with the training data to generate an emulsion likelihood from the well data,
selecting an emulsion model from the set of emulsion models using the testing data,
generating the emulsion likelihood from the well data, and
visualizing the emulsion likelihood through an interactive user interface to explore one or more data scenarios.

12. The system of claim 11, wherein preprocessing the well data comprises:
validating data types of the well data;
cleaning the well data to remove noise;
encoding categorical variables; and
normalizing the well data across different datasets.

13. The system of claim 11, wherein training the set of emulsion models comprises:
executing the set of emulsion models using the training data to generate updates to the set of emulsion models; and
updating the set of emulsion models with the updates to improve a set of predictive accuracies of the set of emulsion models.

14. The system of claim 11, wherein selecting the emulsion model comprises:
applying the testing data to the set of emulsion models to generate a set of predicted emulsion likelihoods;
comparing the set of predicted emulsion likelihoods with a set of observations to measure model performance and generate a set of model accuracies; and
selecting the emulsion model from the set of emulsion models using the set of model accuracies.

15. The system of claim 11, wherein generating the emulsion likelihood comprises:
executing the emulsion model using current data from the well data to generate the emulsion likelihood.

16. The system of claim 11, wherein visualizing the emulsion likelihood comprises:
displaying the emulsion likelihood in a graph on a user interface.

17. The system of claim 11, wherein visualizing the emulsion likelihood comprises:
executing the interactive user interface to display the emulsion likelihood using one or more graphs, charts, and heat maps for different data scenarios and adjust parameters to interactively display potential outcomes.

18. The system of claim 11, further comprising:
transmitting a real-time notification through the interactive user interface based on the emulsion likelihood.

19. The system of claim 11, wherein the selected emulsion model is used to optimize well production parameters.

20. A non-transitory computer readable medium comprising stored instructions executable by at least one processor to perform:
ingesting well data;
preprocessing the well data to generate training data and testing data;
training a set of emulsion models with the training data to generate an emulsion likelihood from the well data;
selecting an emulsion model from the set of emulsion models using the testing data;
generating the emulsion likelihood from the well data; and
visualizing the emulsion likelihood through an interactive user interface to explore one or more data scenarios.
